(19) United States
(12) Patent Application Publication
(10) Pub. No.: US 2025/0089460 A1
(43) Pub. Date: Mar. 13, 2025

(54) DISPLAY PANELS

(71) Applicant: Wuhan China Star Optoelectronics Semiconductor Display Technology Co., Ltd., Wuhan, Hubei (CN)

(72) Inventors: Dan BAI, Wuhan, Hubei (CN); Yu ZHAO, Wuhan, Hubei (CN)

(73) Assignee: Wuhan China Star Optoelectronics Semiconductor Display Technology Co., Ltd., Wuhan, Hubei (CN)

(21) Appl. No.: 18/275,068

(22) PCT Filed: May 12, 2023
(86) PCT No.: PCT/CN2023/094042

§ 371 Date: Jul. 31, 2023

(30) Foreign Application Priority Data
Apr. 19, 2023 (CN) 202310426594.1

(51) Int. Cl. H10K 59/122; H10K 59/12; H10K 59/35; H10K 59/80

(52) U.S. Cl. CPC H10K 59/122; H10K 59/1201; H10K 59/352; H10K 59/80517

(57) ABSTRACT

Display panels are provided according to embodiments of the present disclosure. The display panel includes: a substrate, anodes disposed on the substrate, an inorganic barrier layer, and a pixel definition layer. The inorganic barrier layer includes barrier parts, and the anodes are arranged at intervals between the barrier parts. The pixel definition layer includes pixel definition parts each covering the barrier part and a part of the anode. An orthographic projection of a side of the barrier part adjacent to the substrate on the substrate is located within an orthographic projection of a side of the barrier part away from the substrate on the substrate.

### TECHNICAL FIELD

The present disclosure relates to the field of display technologies, and in particular, to display panels.

### BACKGROUND

At present, as demand for the resolution of display products increases, the market demand for high-resolution organic light-emitting diode (OLED) display panels is increasing. However, in the existing OLED display panel, anodes are formed by wet etching, a degree of a side etching is difficult to control, and a distance between the anodes cannot be reduced, making it difficult to improve the resolution of the display panel.

Therefore, there is an urgent need for display panels to solve the above technical problems.

### SUMMARY OF THE INVENTION

The present disclosure provides display panels, which can alleviate the technical problems that the distance between the anodes of the existing display panel is difficult to reduce, resulting in difficulty in improving the resolution of the display panel.

In order to solve the above technical problems, technical solutions according to the present disclosure are provided as follows.

The present disclosure provides a display panel, including:
a substrate;
anodes disposed on the substrate;
an inorganic barrier layer disposed on the substrate and including barrier parts, and the anodes being arranged at intervals between the barrier parts; and
a pixel definition layer including pixel definition parts covering the barrier parts and a part of each of the anodes;
herein an orthographic projection of a side of each of the barrier parts adjacent to the substrate on the substrate is located within an orthographic projection of a side of the each of the barrier parts away from the substrate on the substrate.

Preferably, the inorganic barrier layer further includes first openings arranged at intervals between the barrier parts, and the anodes are located in the first openings; and
the pixel definition layer further includes second openings arranged at intervals between the pixel definition parts, and each of the second openings is partially located in one of the first openings.

Preferably, a width of an orthographic projection of each of the pixel definition parts between adjacent ones of the second openings on the substrate is less than 2.5 microns.

Preferably, the first barrier subpart does not overlap with the anodes.

Preferably, each of the barrier parts includes a first barrier subpart and a second barrier subpart disposed on a side of the first barrier subpart away from the substrate; and
an orthographic projection of the first barrier subpart on the substrate is located with an orthographic projection of the second barrier subpart on the substrate.

Preferably, a porosity degree of a material of the first barrier subpart is greater than a porosity degree of a material of the second barrier subpart.

Preferably, the material of the first barrier subpart is selected from silicon oxide compounds, and the material of the second barrier subpart is selected from silicon nitride compounds.

Preferably, a thickness of the first barrier subpart is greater than or equal to 100 nm and is less than or equal to 1000 nm; and
a thickness of the second barrier subpart is greater than or equal to 10 nm and is less than or equal to 500 nm.

Preferably, the anodes include one or more first sub-anodes, one or more second sub-anodes, and one or more third sub-anodes;
the display panel further includes a first light-emitting layer disposed on a side of the first sub-anodes away from the substrate, a second light-emitting layer disposed on a side of the second sub-anodes away from the substrate, and a third light-emitting layer disposed on a side of the third sub-anodes away from the substrate;
the light emitted by the first light-emitting layer is red, the light emitted by the second light-emitting layer is green, and the light emitted by the third light-emitting layer is blue; and a thickness of each of the first sub-anodes, a thickness of each of the second sub-anodes, and a thickness of each of the third sub-anodes decrease successively.

Preferably, the thickness of each of the third sub-anodes is less than a thickness of each of the barrier parts.

Preferably, the anodes include first anode subparts, second anode subparts, and third anode subparts; and along a direction from the substrate to the pixel definition layer, each of the first sub-anodes is composed of one of the first anode subparts, one of the second anode subparts, and one of the third anode subparts stacked in sequence, each of the second sub-anodes is composed of one of the first anode subparts and one of the second anode subparts stacked in sequence, and each of the third sub-anodes is composed of one of the first anode subparts.

Preferably, a thickness of each of the first anode subparts is less than or equal to a thickness of the first barrier subpart.

Preferably, each of the first anode subparts includes a first electrode sublayer, a second electrode sublayer, and a third electrode sublayer that are sequentially stacked in a direction away from the substrate; and
materials of the first electrode sublayer and the third electrode sublayer are transparent conductive materials, and a material of the second electrode sublayer is a conductive material with a reflective function.

Preferably, an area of an orthographic projection of each of the second sub-anodes on the substrate is less than an area of an orthographic projection of each of the first sub-anodes on the substrate, and is less than an area of an orthographic projection of each of the third sub-anodes on the substrate.

Preferably, an area of an orthographic projection of each of the first openings corresponding to the second sub-anodes on the substrate is less than an area of an orthographic projection of each of the first openings corresponding to the first sub-anodes on the substrate and
an area of an orthographic projection of each of the first openings corresponding to the second sub-anodes on the substrate is less than an area of an orthographic projection of each of the first openings corresponding to the third sub-anodes on the substrate.

Preferably, a width of an orthographic projection of the first barrier subpart separating adjacent ones of the anodes on the substrate is less than or equal to a distance between adjacent ones of the first anode subparts.

Preferably, an orthographic projection of the second barrier subpart on the substrate overlaps with an orthographic projection of one of the first anode subparts on the substrate.

Preferably, a distance between adjacent ones of the first anode subparts is less than 2 micrometers.

Preferably, the display panel further includes a second barrier layer disposed on the pixel definition parts, and a material of the second barrier layer is an inorganic material.

Preferably, the material of the second barrier layer is selected from inorganic insulation materials.

### Beneficial Effects

In the present disclosure, through the arrangement of the inorganic barrier layer, the anodes are separated by the barrier part. The orthographic projection of the side of the barrier part of the inorganic barrier layer adjacent to the substrate on the substrate is located within the orthographic projection of the side of the barrier part away from the substrate on the substrate, which is beneficial to reduce the distance between the anodes and improve the resolution of the display panel.

### DESCRIPTION OF DRAWINGS

FIG. 1 is a schematic view of a first structure of a display panel according to an embodiment of the present disclosure;

FIG. 2 is a partial schematic view of the first structure of the display panel according to an embodiment of the present disclosure;

FIG. 3 is a schematic top view of the first structure of the display panel according to an embodiment of the present disclosure;

FIG. 4 is a flow chart of steps of a manufacturing method of a display panel according to an embodiment of the present disclosure; and

FIG. 5A to FIG. 5I are schematic flow charts of the manufacturing method of the display panel according to an embodiment of the present disclosure.

### EMBODIMENTS OF THE INVENTION

The present disclosure provides display panels. In order to make the purposes, technical solutions, and effect of the present disclosure clearer, the present disclosure will be further described in detail below with reference to the accompanying drawings and examples. It should be understood that the specific embodiments described here are only used to explain the present disclosure, not to limit the present disclosure.

At present, the existing display panel has the problem that it is difficult to improve the resolution of the display panel due to the difficulty in reducing the distance between the anodes.

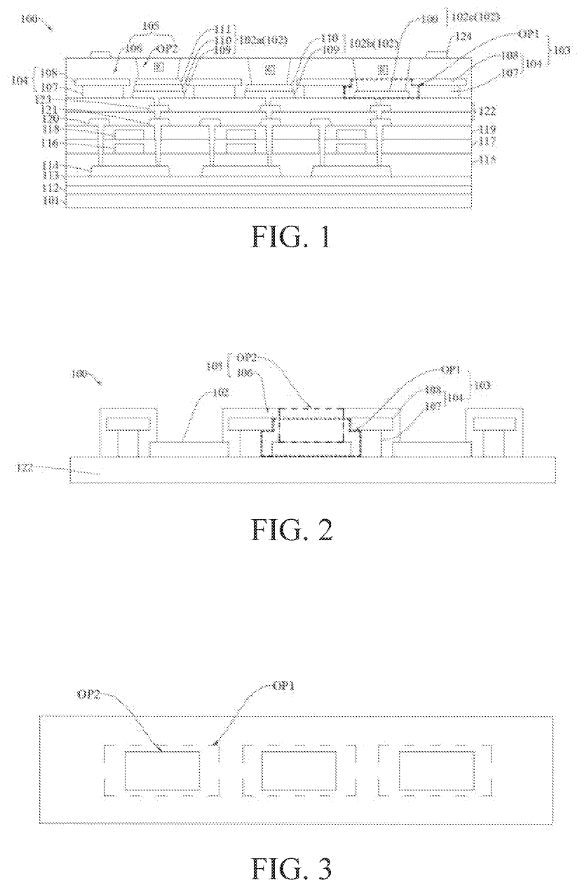

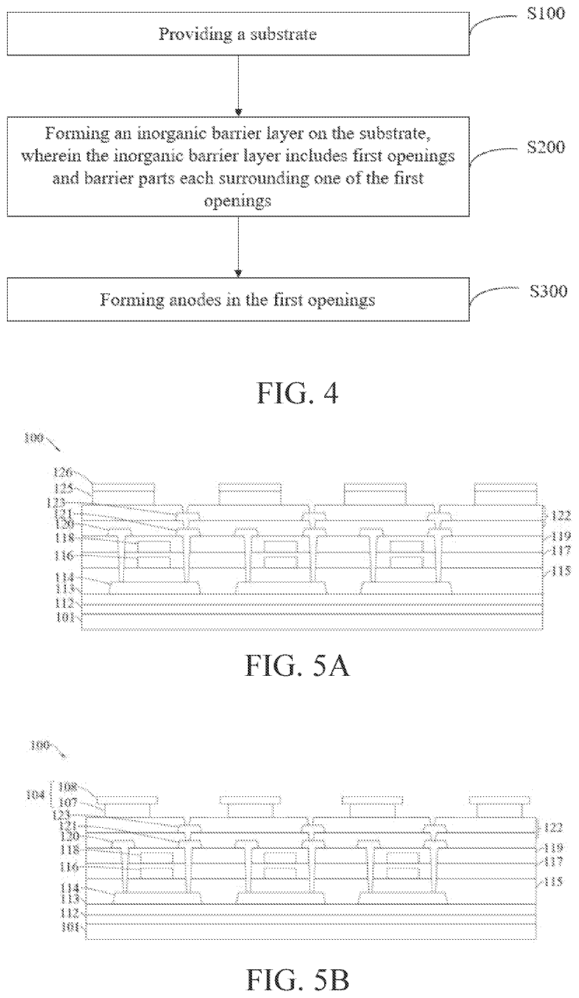

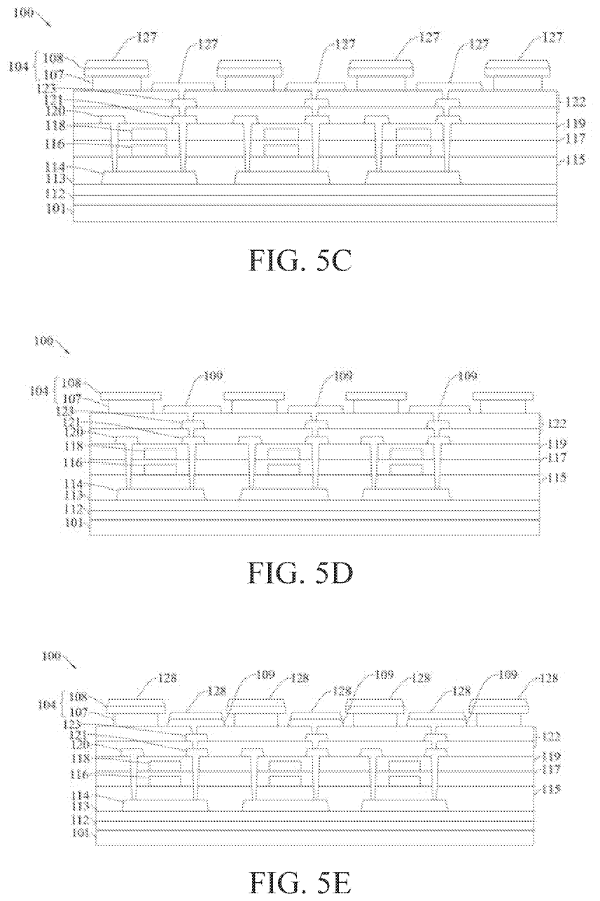

Referring to FIG. 1 to FIG. 3, an embodiment of the present disclosure provides a display panel 100, including:
a substrate 101;
anodes 102 disposed on the substrate 101;
an inorganic barrier layer 103 disposed on the substrate 101 and including barrier parts 104, and the anodes 102 arranged at intervals between the barrier parts 104; and
a pixel definition layer 105 including pixel definition parts 106 covering the barrier parts 104 and a part of each of the anodes 102;
herein, an orthographic projection of a side of each of the barrier parts 104 adjacent to the substrate 101 on the substrate 101 is located within an orthographic projection of a side of the each of the barrier parts 104 away from the substrate 101 on the substrate 101.

In the present disclosure, through the arrangement of the inorganic barrier layer 103, the anodes 102 are separated by the barrier part 104. The orthographic projection of the side of the barrier part 104 of the inorganic barrier layer 103 adjacent to the substrate 101 on the substrate 101 is located within the orthographic projection of the side of the barrier part 104 away from the substrate 101 on the substrate 101, which is beneficial to reduce the distance between the anodes 102 and improve the resolution of the display panel 100.

The technical solutions of the present disclosure will now be described in conjunction with specific embodiments.

Referring to FIG. 1, in this embodiment, the display panel 100 includes the following structure: a substrate 101, a first barrier layer 112, a buffer layer 113, a thin film transistor layer, a planarization layer 122, an auxiliary metal layer 123, anodes 102, an inorganic barrier layer 103, a pixel definition layer 105, organic layers, a cathode, and a package layer.

The substrate 101 may be made of an organic material having insulation properties and being flexible, so as to be heat-treated at a temperature equal to or greater than about 450° C. The substrate 101 may be formed, for example, as a single layer made of polyimide or may be formed as a multi-layer repeatedly stacked by coating and curing polyimide. The substrate 101 may be a flexible substrate formed by coating a polymer material such as polyimide on a support base (not shown) and curing the polymer material. In this case, the substrate 101 may be formed in a multi-layer by repeatedly coating and curing the polymer material. The support base may be made of glass, metal, or ceramics. The polyimide can be coated on the support base by coating processes such as spin coating, slit coating, ink-jet coating, etc. The support base may be removed in subsequent processes.

In some embodiments, the substrate 101 includes a first flexible substrate, an intermediate layer, an adhesive layer, and a second flexible substrate. The first flexible substrate and the second flexible substrate may be made of the same material such as polyimide. The intermediate layer may be made of, for example, an inorganic material including at least one of SiOx and SiNx. The adhesive layer may be made of hydrogenated amorphous silicon (a-Si: H).

The first barrier layer 112 is formed on the substrate 101. The first barrier layer 112 may include various insulation materials (for example, silicon oxide or silicon nitride), and may be a single-layer or multi-layer structure, which is not limited here. The barrier layer provides a planarization layer on an upper surface of the substrate and can block or prevent impurities and moisture from penetrating into light-emitting layers from the substrate 101.

In some embodiments, the first barrier layer 112 may include a first barrier sublayer and a second barrier sublayer formed on the first barrier sublayer. For example, the first barrier sublayer may be formed between the second barrier sublayer and the substrate 10. In practical applications, the first barrier sublayer may be formed by depositing silicon oxide, and subsequently, the second barrier sublayer is formed by depositing silicon nitride through an in-situ process. In this case, the first barrier sublayer can be formed of SiOx or SiON (which can enhance an interfacial bonding performance between the barrier layer and the substrate 101), and the first barrier sublayer can be formed to have a thickness of about 100 nm to about 600 nm. The second barrier sublayer can be formed of SiNx or SiON (which can enhance an interfacial bonding performance between the barrier layer and the buffer layer 113 disposed subsequently), and the second barrier sublayer can be formed to have a thickness of about 50 nm to about 200 nm.

The buffer layer 113 is formed on the first barrier layer 112. The buffer layer 113 may include one or more inorganic insulation layers. The inorganic insulation layer includes materials such as silicon oxide or silicon nitride. The buffer layer 113 provides a planarization layer on the upper surface of the substrate 101 and can block or prevent impurities and moisture from penetrating into the light-emitting layers from the substrate 101.

In some embodiments, the buffer layer 113 includes a first buffer sublayer made of, for example, silicon nitride and a second buffer sublayer made of, for example, silicon oxide. The second buffer sublayer and the first buffer sublayer may be made of silicon nitride having the same film quality (for example, the same density and the same film stress). An oxide film may be provided at an interface between the second buffer sublayer and the first buffer sublayer. The oxide film may be a natural oxide film formed between processes of forming the second barrier sublayer and forming the first buffer sublayer, and may have a thickness of several tens of angstroms or less. In practical applications, a thickness of the first buffer sublayer may be about 50 nm to 100 nm, and a thickness of the second sub buffer layer 24 may be about 100 nm to 300 nm.

The thin film transistor layer includes thin film transistors. The thin film transistor includes a semiconductor 114 formed on the buffer layer 113. The semiconductor 114 may be made of polysilicon. The semiconductor 114 is divided into a channel area, and a source area and a drain area formed on both sides of the channel area. The channel area of the semiconductor 114 is polysilicon without doping impurities, that is, an intrinsic semiconductor. The source area and the drain area are polysilicon doped with conductive impurities, i.e., impurity semiconductors. The impurities doped in the source area and the drain area may be any of P-type impurities and N-type impurities.

The thin film transistor layer further includes a first gate insulation layer 115 covering the semiconductor 114. The first gate insulation layer 115 may be formed as a multi-layer or a single layer of at least one of tetraethyl orthosilicate (TEOS), silicon nitride, and silicon oxide.

The thin film transistor further includes a first gate 116 formed on the first gate insulation layer 115. The first gate 116 overlaps with the channel area. The first gate 116 may be formed as a multi-layer or a single layer including a low-resistance material such as Al, Ti, Mo, Cu, Ni, or alloys thereof, or a material having high corrosion resistance.

The thin film transistor layer further includes a second gate insulation layer 117 covering the first gate 116. The second gate insulation layer 117 may be formed as a multi-layer or a single layer of at least one of tetraethyl orthosilicate (TEOS), silicon nitride, and silicon oxide.

The thin film transistor further includes a second gate 118 formed on the second gate insulation layer 117. The second gate 118 overlaps with the first gate 116. The second gate 118 may be formed as a multi-layer or a single layer including a low-resistance material such as Al, Ti, Mo, Cu, Ni, or alloys thereof, or a material having high corrosion resistance.

The thin film transistor layer further includes a first interlayer insulation layer 119 formed on the second gate 118. The first interlayer insulation layer 119 may be formed as a multi-layer or a single layer of at least one of tetraethyl orthosilicate (TEOS), silicon nitride, and silicon oxide. The first interlayer insulation layer 119, the first gate insulation layer 115, and the second gate insulation layer 117 include a source contact hole and a drain contact hole. The source area and the drain area are respectively exposed through the source contact hole and the drain contact hole.

The thin film transistor further includes a source 120 and a drain 121 arranged in a same layer, both of which are formed on the first interlayer insulation layer 119. The source 120 is connected to the source area through the source contact hole, and the drain 121 is connected to the drain area through the drain contact hole. The source 120 and the drain 121 may be formed as a multi-layer or a single layer including a low-resistance material such as Al, Ti, Mo, Cu, Ni, or alloys thereof, or a material having high corrosion resistance. For example, the source 120 and the drain 121 may be a triple layer of Ti/Cu/Ti, Ti/Ag/Ti, Ti/Al/Ti, or Mo/Al/Mo, or other single-layer or multi-layer structures.

The planarization layer 122 is formed on the source 120 and the drain 121. The planarization layer 122 includes a through hole, and the drain 121 is exposed through the through hole. The planarization layer 122 may be formed as a multi-layer or a single layer of at least one of tetraethyl orthosilicate (TEOS), silicon nitride, and silicon oxide, and can be made of organic materials with low dielectric constants (for example, polyimide).

In some embodiments, the planarization layer 122 includes a first planarization sublayer formed on the source 120 and the drain 121 and a second planarization sublayer formed on the first planarization sublayer. The through hole includes a first through hole penetrating through the first planarization sublayer and a second through hole penetrating through the second planarization sublayer.

The auxiliary metal layer 123 is located between the first planarization sublayer and the second planarization sublayer. The auxiliary metal layer 123 is connected to the drain through the first through hole. The second through hole exposes the auxiliary metal layer 123. The auxiliary metal layer 123 may be formed as a multi-layer or a single layer including a low-resistance material such as Al, Ti, Mo, Cu, Ni, or alloys thereof, or a material having high corrosion resistance. For example, the source and the drain may be a triple layer of Ti/Cu/Ti, Ti/Ag/Ti, Ti/Al/Ti, or Mo/Al/Mo, or other single-layer or multi-layer structures.

Referring to FIG. 1 to FIG. 3, each of the anodes 102 is formed on the planarization layer 122 and is electrically connected to the drain through the through hole.

The inorganic barrier layer 103 further includes first openings OP1 arranged at intervals between the barrier parts 104. The anodes 102 are located in the first openings OP1. That is, the anodes 102 are separated from each other by the barrier parts 104 of the inorganic barrier layer 103.

The pixel definition layer 105 further includes second openings OP2 arranged at intervals between the pixel definition parts 106. The second opening OP2 is partially located in the first opening OP1.

In some embodiments, the inorganic barrier layer 103 is formed on the planarization layer 122. Each of the anodes 102 is exposed through one of the first openings OP1.

Each of the barrier parts 104 of the inorganic barrier layer 103 includes a first barrier subpart 107 and a second barrier subpart 108 disposed on a side of the first barrier subpart 107 away from the substrate 101. That is, the first barrier subpart 107 is formed on the planarization layer 122, and the second barrier subpart 108 is formed on the first barrier subpart 107.

An orthographic projection of the first barrier subpart 107 on the substrate 101 is located within an orthographic projection of the second barrier subpart 108 on the substrate 101. That is, the barrier part 104 presents a shape that is wide at the top and narrow at the bottom, which is beneficial to disconnect adjacent anodes 102 during formation of the anodes 102 and control a size of the anode 102 in the first opening OP1, so that a distance between adjacent anodes 102 can be controlled through a width of the orthographic projection of the barrier part 104 between the first openings OP1 on the substrate 101, so as to reduce the distance between the anodes 102.

The inorganic barrier layer 103 is formed on the planarization layer 122 prior to the anodes 102. The anodes 102 correspond to the first openings OP1 one by one, so that the barrier parts 104 separate the anodes 102 and reduce the distance between the anodes 102.

Materials of the first barrier subpart 107 and the second barrier subpart 108 are both inorganic materials. An etching precision of the inorganic material is greater than that of an organic material forming the pixel definition layer 105, so that it is easier to separate the anodes 102 with a shorter distance, thereby reducing the distance between the anodes 102 and improving the resolution of the display panel 100.

A porosity degree of a material of the first barrier subpart 107 is greater than a porosity degree of a material of the second barrier subpart 108. That is, an etching rate of the material of the first barrier subpart 107 is greater than an etching rate of the material of the second barrier subpart 108. When the first barrier subpart 107 and the second barrier subpart 108 are formed by wet etching, a wet etching rate of the material of the first barrier subpart 107 is greater than a wet etching rate of the material of the second barrier subpart 108. The material of the first barrier subpart 107 may be selected from silicon oxide compounds (such as: SiOx), and the material of the second barrier subpart 108 may be selected from silicon nitride compounds (such as: SiNx).

In some embodiments, the anode 102 includes a first anode subpart 109 disposed adjacent to the substrate. A thickness of the first anode subpart 109 is less than or equal to the thickness of the first barrier subpart 107. Since the inorganic barrier layer 103 is formed on the planarization layer 122 prior to the anodes 102, the first anode subpart 109 is a part of the anode 102 closest to the substrate 101. That the thickness of the first anode subpart 109 is less than or equal to the thickness of the first barrier subpart 107 is conducive to complete disconnection between adjacent first anode subparts 109, thereby controlling the reduction of the distance between the anodes 102 and improving the resolution of the display panel 100. At the same time, since the inorganic barrier layer 103 is formed on the planarization layer 122 prior to the anodes 102, the first barrier subpart 107 may or may not be in contact with the first anode subpart 109, and the first barrier subpart 107 does not cover the anode 102, so that a width of the orthographic projection of the first barrier subpart 107 between the adjacent anodes 102 on the substrate 101 is less than or equal to the distance between adjacent first anode subparts 109. That is, a width of an orthographic projection of the first barrier subpart 107 between adjacent first openings OP1 on the substrate 101 is less than or equal to a distance between adjacent first anode subparts 109 of the anodes 102. In addition, since the inorganic barrier layer 103 is formed on the planarization layer 122 prior to the anodes 102, and the first barrier subpart 107 and the second barrier subpart 108 are both made of inorganic materials, it is more possible to effectively controlling a width of the orthographic projection of the inorganic barrier layer 103 between adjacent first openings OP1 on the substrate 101, and the distance between the first anode subparts 109 formed in the first openings OP1 is effectively reduced. The distance between adjacent first anode subparts 109 is less than 2 microns. For example, the distance between adjacent first anode subparts 109 may be 1.95 microns, 1.9 microns, 1.8 microns, 1.85 microns, 1.75 microns, 1.7 microns, 1.65 microns, 1.6 microns, 1.55 microns, 1.5 microns, 1.45 microns, 1.4 microns, 1.35 microns, 1.3 microns, 1.25 microns, 1.2 microns, 1.1 microns, 1 micron, 0.8 micron, or 0.5 micron, etc., which is beneficial to reduce the distance between the anodes 102 and improve the resolution of the display panel 100. At the same time, when the first anode subpart 109 is formed in the first opening OP1 by a deposition method, the orthographic projection of the first anode subpart 109 on the substrate 101 overlaps with an orthographic projection of the second barrier subpart 108 on the substrate 101, so that the distance between the anodes 102 is reduced, which is beneficial to improve the resolution of the display panel 100.

In some embodiments, the first opening OP1 includes a first sub-opening penetrating through the first barrier subpart 107 and a second sub-opening penetrating through the second barrier subpart 108. Because the inorganic barrier layer 103 is formed on the planarization layer 122 prior to the anodes 102, when the first anode subpart 109 is formed, adjacent first anode subparts 109 are disconnected through the first barrier subpart 107. That is, an area of the orthographic projection of the first anode subpart 109 on the substrate 101 is regulated by an area of an orthographic projection of the second sub-opening on the substrate 101. The area of the orthographic projection of the first anode subpart 109 on the substrate 101 is greater than or equal to the area of the orthographic projection of the second sub-opening on the substrate 101, and the area of the orthographic projection of the first anode subpart 109 on the substrate 101 is less than or equal to an area of an orthographic projection of the first sub-opening on the substrate 101.

In some embodiments, a thickness of the first barrier subpart 107 is greater than or equal to 100 nm and is less than or equal to 1000 nm, which is beneficial to prevent the second barrier subpart 108 from collapsing the first barrier subpart 107. A thickness of the second barrier subpart 108 is greater than or equal to 10 nm and is less than or equal to 500 nm, so as to effectively control the disconnection between adjacent first anode subparts 109.

In some embodiments, the first anode subpart 109 includes a first electrode sublayer, a second electrode sublayer, and a third electrode sublayer that are sequentially stacked in a direction away from the substrate 101. Materials of the first electrode sublayer and the third electrode sublayer are transparent conductive materials, such as indium tin oxide, indium zinc oxide, zinc oxide, indium oxide, and other materials. A material of the second electrode sublayer is a conductive material with a reflective function, such as a conductive metal material (for example: magnesium, silver, gold, calcium, lithium, chromium, aluminum, or one or more of their alloys), etc. The second electrode sublayer of the first anode subpart 109 is generally made of a metal material. An etching rate and an etching degree of the metal material are difficult to control, resulting in difficulty in reduction of the distance between adjacent first anode subparts 109, thereby making it difficult to reduce the distance between the anodes 102. Therefore, through the first anode subpart 109 being located in the first opening OP1, and through the distance between the first anode subparts 109 being controlled by the inorganic barrier layer 103, it is beneficial to reduce the distance between adjacent anodes 102 and improve the resolution of the display panel 100.

A thickness of the first electrode sublayer is greater than or equal to 7 nm and is less than or equal to 60 nm. For example, the thickness of the first electrode sublayer may be 10 nm, 15 nm, 20 nm, 25 nm, 30 nm, 35 nm, 40 nm, 45 nm, 50 nm, or 55 nm. A thickness of the second electrode sublayer is greater than or equal to 50 nm, and the thickness of the first electrode sublayer is less than or equal to 100 nm. For example, the thickness of the second electrode sublayer may be 55 nm, 60 nm, 70 nm, 80 nm, 90 nm, 100 nm, 110 nm, 120 nm, 130 nm, or 140 nm. A thickness of the third electrode sublayer is greater than or equal to 7 nm and the thickness of the first electrode sublayer is less than or equal to 60 nm. For example, the thickness of the third electrode sublayer may be 10 nm, 15 nm, 20 nm, 25 nm, 30 nm, 35 nm, 40 nm, 45 nm, 50 nm, or 55 nm.

The second opening OP2 of the pixel definition layer 105 exposes at least part of the anode 102. A width of an orthographic projection of the pixel definition part 106 between adjacent second openings OP2 on the substrate 101 is less than 2.5 microns. The narrow of the pixel definition part 106 between adjacent second openings OP2 is beneficial to reduce the distance between the anodes 102 and improve the resolution of the display panel 100.

In some embodiments, the pixel definition part 106 is made of an organic material and its patterning accuracy is limited. A second barrier layer disposed on the pixel definition parts 106 may be provided to control a size of the second opening OP2 and a width of the orthographic projection of the pixel definition part 106 between adjacent second openings OP2 on the substrate 101, so as to reduce the distance between the adjacent anodes 102. The display panel 100 further includes the second barrier layer disposed on the pixel definition layer 105. A material of the second barrier layer is an inorganic material, such as indium tin oxide, indium zinc oxide, silicon oxide, silicon nitride, or other materials. The second barrier layer may be removed after the pixel definition layer 105 is formed, so as to avoid affecting subsequent processes and functions of subsequent film layers. Alternatively, the second barrier layer may remain in the display panel 100, and in this case, the material of the second barrier layer is preferably an inorganic insulation material such as silicon oxide or silicon nitride, so as to avoid damage to subsequent processes and functions of subsequent film layers. The pixel definition layer 105 is made of an organic material, which is beneficial to fill a gap that may exist between the anode 102 and the inorganic barrier layer 103, so as to reduce the intrusion of water and oxygen into the organic layers.

The organic layers are formed in the second openings OP2. The organic layers may include one or more light-emitting layers, a hole injection layer, a hole transport layer, an electron transport layer, and an electron injection layer. The hole injection layer is disposed on the anodes 102, the hole transport layer is disposed on the hole injection layer, the light-emitting layer is disposed on the hole transport layer, the electron transport layer is disposed on the light-emitting layer, and the electron injection layer is disposed on the electron transport layer.

The cathode is formed on the pixel definition layer 105 and the organic layers. A material of the cathode may include a transparent conductive material, such as indium tin oxide, indium zinc oxide, zinc oxide, indium oxide, and other materials.

The anodes 102, the organic layers, and the cathode form organic light-emitting elements.

In some embodiments, the display panel 100 includes red organic light-emitting elements, green organic light-emitting elements and blue organic light-emitting elements. Correspondingly, the anodes 102 include first sub-anodes 102a, second sub-anodes 102b, and third sub-anodes 102c. The display panel 100 further includes a first light-emitting layer R disposed on a side of the first sub-anodes 102a away from the substrate 101, a second light-emitting layer G disposed on a side of the second sub-anodes 102b away from the substrate 101, and a third light-emitting layer B disposed on a side of the third sub-anodes 102c away from the substrate 101. The light emitted by the first light-emitting layer R is red, the light emitted by the second light-emitting layer G is green, and the light emitted by the third light-emitting layer B is blue.

Since colors of the light emitted by the first light-emitting layer R, the second light-emitting layer G, and the third light-emitting layer B are different, so that wavelengths of the light emitted by the three are different. In order to improve light extraction efficiency of the red organic light-emitting element, the green organic light-emitting element, and the blue organic light emitting element, cavity length requirements of the red organic light-emitting element, the green organic light-emitting element and the blue organic light emitting element are different. That is, the red organic light-emitting element, the green organic light-emitting element and the blue organic light emitting element requires different distances between the second electrode sublayer of the first anode subpart 109 and the cathode. The cavity lengths of the red organic light-emitting element, the green organic light-emitting element and the blue organic light emitting element decrease successively. Specifically, thicknesses of the first sub-anode 102a, the second sub-anode 102b, and the third sub-anode 102c are gradually reduced. The thickness of the third sub-anode 102c is less than the thickness of the barrier part 104.

In some embodiments, due to the different sensitivities of human eyes to light of different colors, requirements for light-emitting areas of the red organic light-emitting element, the green organic light-emitting element and the blue organic light emitting element in the display panel 100 are different. Areas of orthographic projections of the first sub-anode 102a, the second sub-anode 102b, and the third sub-anode 102c on the substrate 101 are correspondingly different. Human eyes are most sensitive to green light, therefore, the area of the orthographic projection of the second sub-anode 102b on the substrate 101 is less than the area of the orthographic projection of the first sub-anode 102a on the substrate 101 and is less than the area of the orthographic projection of the third sub-anode 102c on the substrate 101. Correspondingly, since the area of the orthographic projection of the anode 102 on the substrate 101 is related to the area of the orthographic projection of the first opening OP1 on the substrate 101, the area of the orthographic projection of the first opening OP1 corresponding to the second sub-anode 102b on the substrate 101 is less than the area of the orthographic projection of the first opening OP1 corresponding to the first sub-anode 102a on the substrate 101 and is less than the area of the orthographic projection of the first opening OP1 corresponding to the third sub-anode 102c on the substrate 101. That is, a distance between orthographic projections of the inorganic barrier layers 103 on both sides of the first opening OP1 corresponding to the second sub-anode 102b on the substrate 101 is less than a distance between orthographic projections of the inorganic barrier layers 103 on both sides of the first opening OP1 corresponding to the first sub-anode 102a on the substrate 101 and is less than a distance between orthographic projections of the inorganic barrier layers 103 on both sides of the first opening OP1 corresponding to the third sub-anode 102c on the substrate 101.

In some embodiments, the anodes 102 further include second anode subparts 110 disposed on sides of the first anode subparts 109 corresponding to the first sub-anodes 102a away from the substrate 101 and sides of the first anode subparts 109 corresponding to the second sub-anodes 102b away from the substrate 101. The anodes 102 further include third anode subparts 111 disposed on sides of the second anode subparts 110 corresponding to the first sub-anodes 102a away from the substrate 101. Along a direction from the substrate 101 to the pixel definition layer 105, the first sub-anode 102a is composed of the first anode subpart 109, the second anode subpart 110, and the third anode subpart 111 stacked in sequence; the second sub-anode 102b is composed of the first anode subpart 109 and the second anode subpart 110 stacked in sequence; and the third sub-anode 102c is composed of the first anode subpart 109. That is, the first sub-anode 102a is composed of the first anode subpart 109, the second anode subpart 110, and the third anode subpart 111 corresponding to the first sub-anode 102a; the second sub-anode 102b is composed of the first anode subpart 109 and the second anode subpart 110 corresponding to the second sub-anode 102b; and the third sub-anode 102c is composed of the first anode subpart 109 corresponding to the third sub-anode 102c. Therefore, so that the thicknesses of the first sub-anode 102a, the second sub-anode 102b, and the third sub-anode 102c are different.

The second anode subparts 110 are located in the first openings OP1 corresponding to the first sub-anodes 102a and the first openings OP1 corresponding to the second sub-anodes 102b, the second anode subpart 110 may or may not be in contact with the inorganic barrier layer 103, and the inorganic barrier layer 103 does not cover the second anode subpart 110. The third anode subparts 111 are located in the first openings OP1 corresponding to the first sub-anodes 102a, the second anode subpart 110 may or may not be in contact with the inorganic barrier layer 103, and the inorganic barrier layer 103 does not cover the second anode subpart 110.

Materials of the second anode subpart 110 and the third anode subpart 111 are selected from transparent conductive materials, such as indium tin oxide, indium zinc oxide, and other materials. A thickness of the second anode subpart 110 is greater than or equal to 20 nm and is less than or equal to 100 nm. For example, the thickness of the second anode subpart 110 may be 30 nm, 40 nm, 50 nm, 60 nm, 70 nm, 80 nm, 90 nm, etc. A thickness of the third anode subpart 111 is greater than or equal to 20 nm and is less than or equal to 100 nm. For example, the thickness of the third anode subpart 11 may be 30 nm, 40 nm, 50 nm, 60 nm, 70 nm, 80 nm, 90 nm, etc., so as to realize the control of the cavity lengths of the red organic light-emitting element and the green organic light-emitting element, and to improve the luminous efficiency of the display panel 100.

The package layer formed on the cathode. The package layer may be formed by alternately laminating one or more organic layers and one or more inorganic layers. The inorganic layer or the organic layer may be provided in plural. The organic layer is made of a polymer, and may be, for example, a laminate layer or single layer, made of any of polyethylene terephthalate, polyimide, polycarbonate, epoxy resin, polyethylene, or polyacrylate. The organic layer may be made of polyacrylate, specifically include a substance obtained by polymerizing a composition including a diacrylate-based monomer and a triacrylate-based monomer. The monomer composition may further include a monoacrylate-based monomer. In addition, a well-known photoinitiator such as TPO may also be included in the monomer composition, but the monomer composition is not limited thereto. The inorganic layer may be a laminated layer or a single layer including metal oxide or metal nitride. For example, the inorganic layer may include any one of SiNx, Al₂O₃, SiO₂, or TiO2.

In some embodiments, the package layer may sequentially include a first inorganic layer, a first organic layer, and a second inorganic layer disposed on the cathode along a direction away from the substrate 101. Furthermore, the package layer may sequentially include a first inorganic layer, a first organic layer, a second inorganic layer, a second organic layer, and a third inorganic layer disposed on the cathode along a direction away from the substrate 101. Furthermore, the package layer may sequentially include a first inorganic layer, a first organic layer, a second inorganic layer, a second organic layer, a third inorganic layer, a third organic layer, and a fourth inorganic layer disposed on the cathode along a direction away from the substrate 101.

In some embodiments, the display panel 100 further includes a metal halide layer between the package layer and the cathode. The metal halide layer may include LiF. The metal halide layer can prevent the cathode from being destroyed when the first inorganic layer of the package layer is formed by sputtering or plasma deposition.

In some embodiments, the display panel 100 further includes spacer columns 124 disposed on a side of the pixel definition part 106 away from the substrate 101. A material of the spacer column 124 is an organic material, which is configured to separate a photomask during the formation of the organic layers, so as to protect structures such as the pixel definition parts 106 in the display panel 100.

In embodiments of the present disclosure, through the arrangement of the inorganic barrier layer 103, the anodes 102 are separated by the barrier part 104. The orthographic projection of the side of the barrier part 104 of the inorganic barrier layer 103 adjacent to the substrate 101 on the substrate 101 is located within the orthographic projection of the side of the barrier part 104 away from the substrate 101 on the substrate 101, which is beneficial to reduce the distance between the anodes 102 and improve the resolution of the display panel 100.

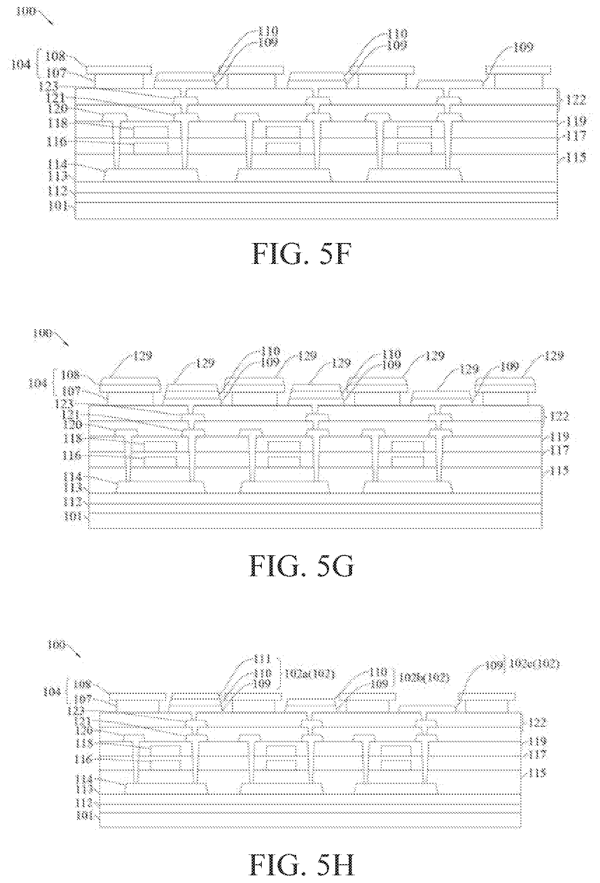

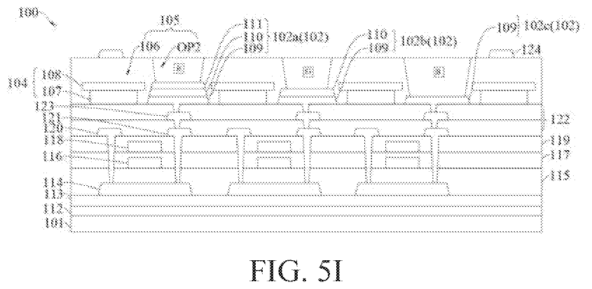

Referring to FIG. 4 and FIG. 5A to FIG. 5I, embodiments of the present disclosure further provide a manufacturing method of a display panel, including steps S100, S200, and S300.

The step S100 includes: providing a substrate 101.

In this embodiment, the material of the substrate 101 and the specific structure of the substrate 101 have been described in detail in the aforementioned display panel 100, and will not be repeated here.

Referring to FIG. 5A and FIG. 5B, the step S200 includes: forming an inorganic barrier layer 103 on the substrate 101. The inorganic barrier layer 103 includes first openings OP1 and barrier parts 104 each surrounding one of the first openings OP1.

Herein, an orthographic projection of a side of each of the barrier parts 104 adjacent to the substrate 101 on the substrate 101 is located within an orthographic projection of a side of the each of the barrier parts 104 away from the substrate 101 on the substrate 101.

In some embodiments, the step S200 further includes:
a step S210, forming a first inorganic insulation layer on the substrate 101;
a step S220, forming a second inorganic insulation layer on the first inorganic insulation layer; and
a step S230, subjecting the first inorganic insulation layer and the second inorganic insulation layer to a first patterning treatment to respectively form first barrier subparts 107 and second barrier subparts 108.

Herein, an orthographic projection of the first barrier subpart 107 on the substrate 101 is located within an orthographic projection of the second barrier subpart 108 on the substrate 101.

In some embodiments, the first inorganic insulation layer and the second inorganic insulation layer may be formed by chemical vapor deposition or physical vapor deposition

In some embodiments, a material of the first inorganic insulation layer is SiNx, and a material of the second inorganic insulation layer is SiOx.

In some embodiments, the step S230 further includes steps S231 and S232.

Referring to FIG. 5A, the step S231 includes: subjecting the first inorganic insulation layer and the second inorganic insulation layer to a first sub-patterning treatment to form a first inorganic layer 125 and a second inorganic layer 126.

The first patterning treatment is a dry etching process, the first inorganic layer includes first preset sub-openings, and the second inorganic layer includes second preset sub-openings.

Referring to FIG. 5B, the step S232 includes: subjecting the first inorganic layer 125 and the second inorganic layer 126 to a second sub-patterning treatment to form the first barrier subparts 107 and the second barrier subparts 108.

The second patterning treatment is a wet etching process. A porosity degree of the material of the first inorganic insulation layer and a porosity degree of the material of the second inorganic insulation are different, and the degrees of side etching of the two inorganic insulation layers in the wet etching process are different. A wet etching rate of the first inorganic layer 125 is greater than a wet etching rate of the second inorganic layer 126, so that the orthographic projection of the first barrier subpart 107 on the substrate 101 is located within the orthographic projection of the second barrier subpart 108 on the substrate 101.

The specific structures of the first barrier subpart 107 and the second barrier subpart 108 have been described in detail in the aforementioned display panel 100, and will not be repeated here.

Referring to FIG. 5C to FIG. 5H, the step S300 includes: forming anodes 102 in the first openings OP1.

The specific structure of the anodes 102 has been described in detail in the aforementioned display panel 100, and will not be repeated here.

In some embodiments, the anodes 102 include the first sub-anodes 102a, the second sub-anodes 102b, and the third sub-anodes 102c, and thicknesses of the first sub-anode 102a, the second sub-anode 102b, and the third sub-anode 102c decrease successively. At this point, the step S300 further includes steps S310, S320, and S330.

The step S310 includes: forming the first anode subparts 109 in the first openings OP1.

In some embodiments, the step S310 includes steps S311 and S312.

Referring to FIG. 5C, the step S311 includes: forming a first anode material layer 127 on the substrate 101.

In this embodiment, the first anode material layer 127 may be formed by chemical vapor deposition or physical vapor deposition of a first anode material. The first anode material layer 127 includes a first sub-electrode material layer, a second sub-electrode material layer, and a third sub-electrode material layer. Materials of the first sub-electrode material layer and the third sub-electrode material layer are selected from one or more of indium tin oxide or indium zinc oxide. A material of the second sub-electrode material layer is silver.

Due to the presence of the inorganic barrier layer 103, the first anode material layer 127 includes a first part in the first openings OP1 and a second part on the inorganic barrier layer 103 between adjacent first openings OP1, and the first part in adjacent first openings OP1 is thus disconnected.

Referring to FIG. 5D, the step S312 includes: subjecting the first anode material layer 127 to a second patterning treatment to form the first anode subparts 109.

The second patterning treatment is a wet etching process for removing the second part of the first anode material layer 127, and the remaining first part forms the first anode subparts 109 located in each of the first openings OP1.

The step S320 includes: forming second anode subparts 110 on the first anode subparts 109 corresponding to the first sub-anodes 102a.

In some embodiments, the step S320 further includes steps S321 and S322.

Referring to FIG. 5E, the step S321 includes: forming a second anode material layer 128 on the substrate 101.

In this embodiment, the second anode material layer 128 may be formed by chemical vapor deposition or physical vapor deposition of a second anode material, and the second anode material is selected from one or more of indium tin oxide or indium zinc oxide.

Due to the presence of the inorganic barrier layer 103, the second anode material layer 128 includes a third part in the first openings OP1 corresponding to the first sub-anodes 102a, a fourth part in the first openings OP1 corresponding to the second sub-anodes 102b, a fifth part in the first openings OP1 corresponding to the third sub-anodes 102c, and a sixth part on the inorganic barrier layer 103 between adjacent first openings OP1.

Referring to FIG. 5F, the step S322 includes: subjecting the second anode material layer 128 to a third patterning treatment to form the second anode subparts 110.

The third patterning treatment is a wet etching process, which is configured to remove the fifth part and the sixth part of the second anode material layer 128, and the remaining third part and fourth part form the second anode subparts 110.

The step S330 includes: forming third anode subparts 111 on the second anode subparts 110 corresponding to the second sub-anodes 102b.

In some embodiments, the step S330 further includes steps S331 and S332.

Referring to FIG. 5G, the step S331 includes: forming a third anode material layer 129 on the substrate 101.

In this embodiment, the third anode material layer 129 may be formed by chemical vapor deposition or physical vapor deposition of a third anode material. The third anode material is selected from one or more of indium tin oxide or indium zinc oxide.

Due to the presence of the inorganic barrier layer 103, the third anode material layer 129 includes a seventh part in the first openings OP1 corresponding to the first sub-anodes 102a, an eighth part in the first openings OP1 corresponding to the second sub-anodes 102b, a ninth part in the first openings OP1 corresponding to the third sub-anodes 102c, and a tenth part on the inorganic barrier layer 103 between adjacent first openings OP1.

Referring to FIG. 5H, the step S332 includes: subjecting the third anode material layer 129 to a fourth patterning treatment to form the third anode subparts 111.

The fourth patterning treatment is a wet etching process, which is configured to remove the eighth part, the ninth part, and the tenth part of the third anode material layer 129, and the remaining seventh part forms the third anode subparts 111.

In some embodiments, after the step S300, the manufacturing method of the display panel further includes a step S400.

Referring to FIG. 5I, the step S400 includes: forming a pixel definition layer 105 on the inorganic barrier layer 103 and the anodes 102.

Herein, the pixel definition layer 105 includes second openings OP2 and pixel definition parts 106 each surrounding one of the second openings OP2. The pixel definition part 106 covers the barrier part 104 and a part of the anode 102, and the second opening OP2 is partially located within the first opening OP1.

The specific structure of the pixel definition layer 105 has been described in detail in the aforementioned display panel 100, and will not be repeated here.

After the step S400, the manufacturing method of the display panel further includes:

a step S500, forming spacer columns 124 on the pixel definition parts 106.

In some embodiments, between the steps S100 and S200, the manufacturing method of the display panel further includes steps of forming a barrier layer, a buffer layer, a thin film transistor layer, a planarization layer 122, an auxiliary metal layer 123. Structures and materials of the barrier layer, the buffer layer, the thin film transistor layer, the planarization layer 122, and the auxiliary metal layer 123 have been described in detail in the aforementioned display panel 100, and will not be repeated here.

In the manufacturing method of the display panel provided in embodiments of the present disclosure, through the arrangement of the inorganic barrier layer 103, the anodes 102 are separated by the barrier part 104. The orthographic projection of the side of the barrier part 104 of the inorganic barrier layer 103 adjacent to the substrate 101 on the substrate 101 is located within the orthographic projection of the side of the barrier part 104 away from the substrate 101 on the substrate 101, which is beneficial to reduce the distance between the anodes 102 and improve the resolution of the display panel 100.

Embodiments of the present disclosure discloses a display panel, which includes a substrate, anodes disposed on the substrate, an inorganic barrier layer, and a pixel definition layer. The inorganic barrier layer includes barrier parts, the anodes are arranged at intervals between the barrier parts. The pixel definition layer includes pixel definition parts. The pixel definition part covers the barrier part and a part of the anode. The orthographic projection of the side of the barrier part of the inorganic barrier layer adjacent to the substrate on the substrate is located within the orthographic projection of the side of the barrier part away from the substrate on the substrate. In the present disclosure, through the arrangement of the inorganic barrier layer, the anodes are separated by the barrier part. The orthographic projection of the side of the barrier part of the inorganic barrier layer adjacent to the substrate on the substrate is located within the orthographic projection of the side of the barrier part 104 away from the substrate on the substrate, which is beneficial to reduce the distance between the anodes and improve the resolution of the display panel.

It can be understood that those skilled in the art can make equivalent replacements or changes according to the technical solutions and inventive concept of the present disclosure, and all these changes or replacements should fall within the protection scope of the appended claims of the application.

1. A display panel, comprising:
a substrate;
anodes disposed on the substrate;
an inorganic barrier layer disposed on the substrate and comprising barrier parts, wherein and the anodes are arranged at intervals between the barrier parts; and
a pixel definition layer comprising pixel definition parts covering the barrier parts and a part of each of the anodes,
wherein an orthographic projection of a side of each of the barrier parts adjacent to the substrate on the substrate is located within an orthographic projection of a side of the each of the barrier parts away from the substrate on the substrate.

2. The display panel according to claim 1, wherein the inorganic barrier layer further comprises first openings arranged at intervals between the barrier parts, and the anodes are located in the first openings; and
the pixel definition layer further comprises second openings arranged at intervals between the pixel definition parts, and each of the second openings is partially located in one of the first openings.

3. The display panel according to claim 2, wherein a width of an orthographic projection of each of the pixel definition parts between adjacent ones of the second openings on the substrate is less than 2.5 microns.

4. (canceled)

5. The display panel according to claim 1, wherein each of the barrier parts comprises a first barrier subpart and a second barrier subpart disposed on a side of the first barrier subpart away from the substrate; and
an orthographic projection of the first barrier subpart on the substrate is located with an orthographic projection of the second barrier subpart on the substrate.

6. The display panel according to claim 5, wherein a porosity degree of a material of the first barrier subpart is greater than a porosity degree of a material of the second barrier subpart.

7. The display panel according to claim 6, wherein the material of the first barrier subpart is selected from silicon oxide compounds, and the material of the second barrier subpart is selected from silicon nitride compounds.

8. The display panel according to claim 5, wherein a thickness of the first barrier subpart is greater than or equal to 100 nm and is less than or equal to 1000 nm; and
a thickness of the second barrier subpart is greater than or equal to 10 nm and is less than or equal to 500 nm.

9. The display panel according to claim 5, wherein the anodes comprise one or more first sub-anodes, one or more second sub-anodes, and one or more third sub-anodes;
the display panel further comprises a first light-emitting layer disposed on a side of the first sub-anodes away from the substrate, a second light-emitting layer disposed on a side of the second sub-anodes away from the substrate, and a third light-emitting layer disposed on a side of the third sub-anodes away from the substrate;
light emitted by the first light-emitting layer is red, light emitted by the second light-emitting layer is green, and light emitted by the third light-emitting layer is blue; and
a thickness of each of the first sub-anodes, a thickness of each of the second sub-anodes, and a thickness of each of the third sub-anodes decrease successively.

10. The display panel according to claim 9, wherein the thickness of each of the third sub-anodes is less than a thickness of each of the barrier parts.

11. The display panel according to claim 9, wherein the anodes comprise first anode subparts, second anode subparts, and third anode subparts; and
along a direction from the substrate to the pixel definition layer, each of the first sub-anodes is composed of one of the first anode subparts, one of the second anode subparts, and one of the third anode subparts stacked in sequence, each of the second sub-anodes is composed of one of the first anode subparts and one of the second anode subparts stacked in sequence, and each of the third sub-anodes is composed of one of the first anode subparts.

12. The display panel according to claim 11, wherein a thickness of each of the first anode subparts is less than or equal to a thickness of the first barrier subpart.

13. The display panel according to claim 11, wherein each of the first anode subparts comprises a first electrode sublayer, a second electrode sublayer, and a third electrode sublayer that are sequentially stacked in a direction away from the substrate; and
materials of the first electrode sublayer and the third electrode sublayer are transparent conductive materials, and a material of the second electrode sublayer is a conductive material with a reflective function.

14. The display panel according to claim 9, wherein an area of an orthographic projection of each of the second sub-anodes on the substrate is less than an area of an orthographic projection of each of the first sub-anodes on the substrate, and is less than an area of an orthographic projection of each of the third sub-anodes on the substrate.

15. The display panel according to claim 14, wherein an area of an orthographic projection of each of the first openings corresponding to the second sub-anodes on the substrate is less than an area of an orthographic projection of each of the first openings corresponding to the first sub-anodes on the substrate, and is less than an area of an orthographic projection of each of the first openings corresponding to the third sub-anodes on the substrate.

16. The display panel according to claim 11, wherein a width of an orthographic projection of the first barrier subpart separating adjacent ones of the anodes on the substrate is less than or equal to a distance between adjacent ones of the first anode subparts.

17. The display panel according to claim 16, wherein an orthographic projection of the second barrier subpart on the substrate overlaps with an orthographic projection of one of the first anode subparts on the substrate.

18. The display panel according to claim 16, wherein a distance between adjacent ones of the first anode subparts is less than 2 micrometers.

19. The display panel according to claim 1, further comprising a second barrier layer disposed on the pixel definition parts, wherein a material of the second barrier layer is an inorganic material.

20. The display panel according to claim 19, wherein the material of the second barrier layer is selected from inorganic insulation materials.

21. The display panel according to claim 5, wherein the first barrier subpart does not overlap with the anodes.
